(19) United States
(12) Patent Application Publication
(10) Pub. No.: US 2004/0145055 A1
(43) Pub. Date: Jul. 29, 2004

(54) Semiconductor device and thin film forming method

(76) Inventor: Kiyotaka Kobayashi, Sakata-shi (JP)

Correspondence Address: EDWARDS & ANGELL, LLP, P.O. BOX 55874, BOSTON, MA, 02205, US

(21) Appl. No.: 10/643,529

(22) Filed: Aug. 19, 2003

(30) Foreign Application Priority Data
Aug. 19, 2002 (JP) 2002-238496

(51) Int. Cl. H01L 29/40

(52) U.S. Cl. 257/751

(57) ABSTRACT

A liner film and a cap film sandwich an FSG film above a lower wiring layer, thereby insulating fluorine contained in the FSG film and preventing fluorine from damaging on the lower wiring layer.

### BACKGROUND OF THE INVENTION

The present invention relates to semiconductor devices and methods for manufacturing thin films. More particularly, the invention is preferably applicable when using a fluorosilicate glass as an insulating film between wiring layers.

In some semiconductor devices of prior art, a fluorosilicate glass is used so as to lower a dielectric constant of an interlayer insulating film to be used between wiring layers.

FIG. 9 is a sectional view showing a schematic configuration of wiring layers in a semiconductor device of prior art.

In FIG. 9, a lower wiring layer 22 is formed on an insulating layer 21 and comprises a structure of multi layers including, for example, a TiN film 22a, an Al-Cu film 22b, a Ti film 22c and a TiN film 22d.

Here, the TiN film 22a provided under the Al-Cu film 22b functions as a barrier film and restrains a junction punch-through, which occurs when multi layered wirings contact with Si, and increase the contact resistance due to Si deposition.

Also, the Ti film 22c and the TiN film 22d provided on the Al-Cu film 22b reduce the contact resistance, function as antireflection films and prevent electromigration.

Moreover, a fluorosilicate glass film (hereinafter referred to as FSG film) 23 is formed on the lower wiring layer 22, and a silicone oxide film 24 is formed on the FSG film 23. In the silicon oxide film 24, a tungsten plug 25 connected to the lower wiring layer 22 is embedded.

Furthermore, provided over the silicon oxide film 24 is an upper wiring layer 26 having a structure of four layers including, for example, a TiN film 26a, an Al-Cu film 26b, a Ti film 26c and a TiN film 26d. The upper wiring layer 26 is connected to the lower wiring layer 22 via the tungsten plug 25.

FIGS. 10(a)-10(c) and FIGS. 11(a)-11(c) are sectional views illustrating a method of manufacturing wiring layers in a semiconductor device of prior art.

In FIG. 10(a), TiN, Al-Cu, Ti and TiN, for example, are sputtered in turn onto the insulating film 21, and a multi layered film comprising TiN, Al-Cu, Ti and TiN is patterned by photolithography and etching techniques so as to form the lower wiring layer 22 on the insulating film 21.

Next, as shown in FIG. 10(b), the FSG film 23 is formed on the lower wiring layer 22 by a method such as high-density plasma CVD, and the FSG film 23 is annealed in the nitrogen atmosphere, thereby removing unstable fluorine components in the FSG film 23.

Subsequently, as shown in FIG. 10(c), the silicon oxide film 24 is formed on the FSG film 23 by conducting plasma CVD using Tetraethoxysilane (TEOS) gas, for instance.

Then, as shown in FIG. 11(a), the surface of the silicon oxide film 24 is polished, for example, by Chemical Mechanical Polishing (CMP) to be planarized.

Next, as shown in FIG. 11(b), a via hole 16 is formed in the FSG film 23 and the silicon oxide film 24 over the lower wiring layer 22 by photolithography and etching techniques so that tungsten can be grown selectively on the lower wiring layer 22. Thereby, the tungsten plug 25 is formed on the lower wiring layer 22.

Subsequently, as shown in FIG. 11(c), TiN, Al-Cu, Ti and TiN, for instance, are sputtered in turn onto the silicon oxide film 24. Then, a multi layered film comprising TiN, Al-Cu, Ti and TiN is patterned by photolithography and etching techniques so as to form the upper wiring layer 26 on the silicon oxide film 24.

However, when forming the FSG film 23 on the lower wiring layer 22, fluorine contained in the FSG film 23 is degassed, thereby affecting and corroding the lower wiring layer 22.

Moreover, the FSG film 23 is formed by high-density plasma CVD in order to satisfy the embedded features of the films forming the lower wiring layer 22, and the silicon oxide film 24 is formed by regular plasma CVD in order to suppress generation of particles.

Therefore, a device needs to be replaced with another when forming the silicon oxide film 24 on the FSG film 23, and at this time, the FSG film 23 occasionally gets exposed to the atmosphere.

When exposed to the atmosphere, then the FSG film 23 takes up moisture, so that hydrogen fluoride is produced in it.

Then, if heat treatment is conducted on the FSG film 23 under the condition that hydrogen fluoride is produced within the FSG film 23, fluorine reacts with Ti due to the degassing, thereby generating fluoride such as TiF on the lower wiring layer 22.

Therefore, there has been a problem with semiconductor devices of prior art in that covering the lower wiring layer 22 with the FSG film 23 increases resistance of the lower wiring layer 22, thereby deteriorating the characteristics of the semiconductor device.

In light of the above problem, the objective of the present invention is to provide a semiconductor device and a thin film manufacturing method capable of restraining damages from fluorine on a wiring layer covered with an FSG film.

In order to solve the above problems, a semiconductor device according to Claim 1 comprises a fluorine-insulating film formed on a wiring layer and a fluorosilicate glass film formed on the wiring layer through the fluorine-insulating film.

With this arrangement, fluorine contained in the fluorosilicate glass film can be prevented from directly touching the wiring layer. In addition, even when using the fluorosilicate glass film as an interlayer insulating film, it is possible to prevent fluorine from affecting and corroding the wiring layer covered with the fluorosilicate glass film.

Therefore, it is possible to improve the yield of manufacturing semiconductor devices and also the reliability of the devices.

Moreover, a semiconductor device according to Claim 2 comprises a fluorosilicate glass film for insulating a wiring layer and a fluorine-insulating film formed so as to sandwich the fluorosilicate glass film from above and below.

With this arrangement, fluorine contained in the fluorosilicate glass film is confined therein and prevented from detaching therefrom. At the same time, it is possible to reduce moisture absorption of the fluorosilicate glass film.

Accordingly, it is possible to prevent fluorine from affecting and corroding the wiring layer covered with the fluorosilicate glass film. At the same time, rising of a wiring resistance of the wiring layer is suppressed, thereby restraining deterioration of characteristics of the semiconductor device while improving the reliability thereof.

Moreover, in the semiconductor device according to Claim 3, the fluorine-insulating film comprises an undoped silicon oxide film.

Accordingly, it is possible to laminate the fluorine-insulating film and the fluorosilicate glass film by alternately mixing a fluorine dopant and not mixing a fluorine dopant, and the fluorine-insulating film can efficiently be formed with an in-situ process.

In addition, in the semiconductor device according to Claim 4, the wiring layer comprises a structure including TiN, Al-Cu, Ti and TiN.

With this arrangement, fluorine contained in the fluorosilicate glass film is reacted with Ti so as to prevent a fluoride such as TiF from being produced on the wiring layer. Accordingly, wiring layers of a high aspect ratio can efficiently be formed with the spacing therebetween being narrow.

Furthermore, a thin film manufacturing method according to Claim 5 comprises a step of forming an undoped silicon oxide film on a wiring layer and a step of forming a fluorosilicate glass film on the undoped silicon oxide film.

With this method, fluorine contained in the fluorosilicate glass film can be prevented from directly touching the wiring layer, and even when using the fluorosilicate glass film as an interlayer insulating film, it is possible to restrain fluorine from affecting the wiring layer covered with the fluorosilicate glass film and prevent it from corroding the wiring layer.

In addition, the thin film manufacturing method according to Claim 6 further comprises a step of forming an undoped silicon oxide film onto the fluorosilicate glass film.

With this method, the fluorosilicate glass film can be sandwiched from above and below with the undoped silicon oxide film, thereby restraining degassing of fluorine and reducing moisture absorption of the fluorosilicate glass film. Therefore, it is possible to suppress deterioration of the characteristics of the semiconductor device while improving the reliability thereof.

Also, in the thin film forming method according to Claim 7, the undoped silicon oxide film and the fluorosilicate glass film are continuously formed by alternately mixing a fluorine dopant and not mixing a fluorine dopant.

With this method, the undoped silicon oxide film and the fluorosilicate glass film can be laminated with an in-situ process, and the device does not need to be replaced with another in forming the undoped silicon oxide film onto the fluorosilicate glass film.

Consequently, it is possible to prevent the fluorosilicate glass film from being exposed to atmosphere and also restrain it from taking up moisture, so that degassing of fluorine can be suppressed.

### BRIEF DESCRIPTION OF DRAWINGS

FIG. 1 is a sectional view showing a schematic structure of wiring layers in a semiconductor device according to the first embodiment of the invention.

FIGS. 2(a)-2(c) are sectional views illustrating a method of manufacturing the wiring layers in the semiconductor device according to the first embodiment of the invention.

FIGS. 3(a)-3(c) are sectional views illustrating the method of manufacturing the wiring layers in the semiconductor device according to the first embodiment of the invention.

FIG. 4 is a sectional view illustrating the method of manufacturing the wiring layers in the semiconductor device according to the first embodiment of the invention.

FIG. 5 is a sectional view showing a schematic structure of wiring layers in a semiconductor device according to the second embodiment of the invention.

FIGS. 6(a)-6(c) are sectional views illustrating a method of manufacturing the wiring layers in the semiconductor device according to the second embodiment of the invention.

FIGS. 7(a)-7(c) are sectional views illustrating the method of manufacturing the wiring layers in the semiconductor device according to the second embodiment of the invention.

FIG. 8 is a sectional view illustrating the method of manufacturing the wiring layers in the semiconductor device according to the second embodiment of the invention.

FIG. 9 is a sectional view showing a schematic structure of wiring layers in a semiconductor device of prior art.

FIGS. 10(a)-10(c) are sectional views illustrating a method of manufacturing the wiring layers in the semiconductor device of prior art.

FIGS. 11(a)-11(c) are sectional views illustrating the method of manufacturing the wiring layers in the semiconductor device of prior art.

### DETAILED DESCRIPTION OF THE INVENTION

A semiconductor device and a thin film manufacturing method according to the embodiments of the invention are explained below with reference to the drawings.

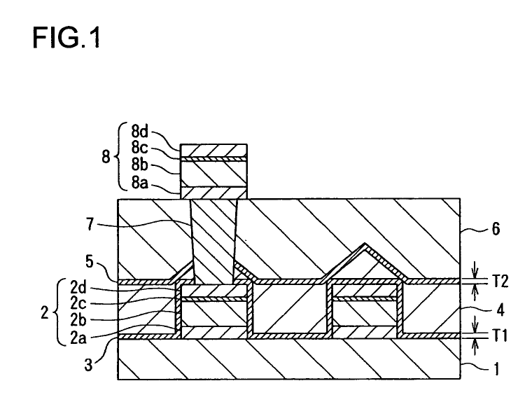

FIG. 1 is a sectional view showing a schematic configuration of wiring layers in the semiconductor device according to the first embodiment of the invention.

In FIG. 1, a lower wiring layer 2 is formed on an insulating layer 1 and comprises a structure of multi layers including, for example, a TiN film 2a, an Al-Cu film 2b, a Ti film 2c and a TiN film 2d.

Here, it is possible to set the thickness of the TiN film 2a to about 300 to 400 Å, for example, that of the Al-Cu film 2b to about 3000 to 10000 Å, for example, that of the Ti film 2c to about 200 Å, for example, and that of the TiN film 2d to about 600 to 1000 Å, for example.

Furthermore, an FSG film 4 sandwiched by a liner film 3 and a cap film 5 from above and below is formed on the lower wiring layer 2.

Here, the liner film 3 and the cap film 5 insulate fluorine contained in the FSG film 4, and for example, undoped silicon oxide films may be used as these films.

In addition, a silicon oxide film 6 is formed on the cap film 5, and a tungsten plug 7 connected to the lower wiring layer 2 is embedded in the silicon oxide film 6.

Then, an upper wiring layer 8 comprising a structure of four layers including a TiN film 8a, an Al-Cu film 8b, a Ti film 8c and a TiN film 8d, for example, is formed on the silicon oxide film 6 and connected to the lower wiring layer 2 via the tungsten plug 7.

Here, sandwiching the FSG film 4 with the liner film 3 and the cap film 5 can prevent degassing of fluorine contained in the FSG film 4 and also keep the FSG film 4 from taking up moisture. Consequently, even when covering the lower wiring layer 2 with the FSG film 4, it is possible to prevent Ti of the lower wiring layer 2 from getting fluoride and TiF from being formed on the lower wiring layer 2.

For example, a T_{DS} analysis result reveals that fluorine was degassed in response to about 150° C. heat treatment in the case of the FSG film 4 alone while the temperature corresponding to the degassing was raised to about 250° C. by sandwiching the FSG film 4 with the liner film 3 and the cap film 5.

Moreover, a value about 3.2 to 3.8 can be established as a dielectric constant of the FSG film 4, so that the dielectric constant can be lowered in comparison with the case of using a silicon dioxide film with a dielectric constant about 4.0 to 4.2

Therefore, it is possible to suppress increase in a wiring resistance of the lower wiring layer 2 while lowering the dielectric constant of an interlayer insulating film on the lower wiring layer 2. Thereby, a wiring delay is prevented, so that the characteristics of the semiconductor device can be improved.

Also, a thickness T1 of the liner film 3 is preferably about 500 to 700 Å, for example, and thereby it is possible to maintain a gap-fill characteristic and a coverage of the liner film 3 to be formed on the lower wiring layer 2. At the same time, it is possible to suppress an increase in the dielectric constant of the interlayer insulating film formed on the lower wiring layer 2 while effectively insulating fluorine contained in the FSG film 4.

Also, a thickness T2 of the cap film 5 is preferably about 1000 Å, for example, thereby restraining rising of the dielectric constant of the interlayer insulating film formed on the lower wiring layer 2 while maintaining a moisture-proof effect on the FSG film 4.

In addition, the structure of the lower wiring layer 2 may be the one including TiN, Al, Ti and TiN or the one including TiN, Al-Cu and TiN, besides the structure of multi layers including the TiN film 2a, the Al-Cu film 2b, the Ti film 2c and the TiN film 2d.

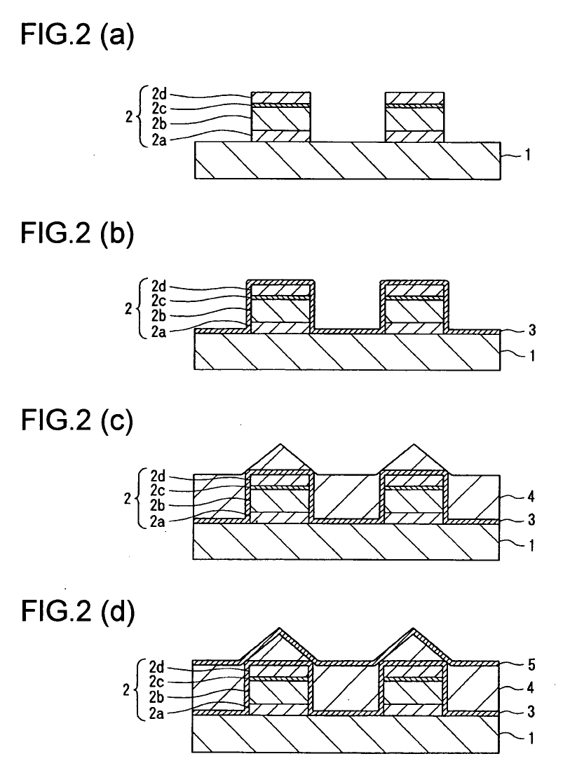

FIG. 2(a) to FIG. 4 are sectional views illustrating a method of manufacturing wiring layers in the semiconductor device according to the first embodiment of the invention.

In FIG. 2(a), for example, TiN, Al-Cu, Ti and TiN are sputtered in turn onto the insulating film 1, and a multi layered film comprising TiN, Al-Cu, Ti and TiN is patterned by photolithography and etching techniques, thereby forming the lower wiring layer 2 on the insulating film 1.

Then, as shown in FIG. 2(b), the liner film 3 such as an undoped silicon oxide film is formed so as to cover the lower wiring layer 2 by a method such as high-density plasma CVD.

Next, as shown in FIG. 2(c), the FSG film 4 is formed on the liner film 3 by a method such as high-density plasma CVD and is annealed in a nitrogen atmosphere, thereby removing unstable fluorine components in the FSG film 4.

Subsequently, as shown in FIG. 2(d), for example, high-density plasma CVD is conducted in a manner that the FSG film 4 after being annealed is not exposed to the atmosphere. Consequently, the cap film 5 such as an undoped silicon oxide film is formed on the FSG film 4.

Here, the silicon oxide film is continuously formed by alternately mixing a fluorine dopant and not mixing a fluorine dopant within the same chamber, for example, with an in-situ process as a method of forming the liner film 3, the FSG film 4 and the cap film 5.

Consequently, the FSG film 4 can be sandwiched with the liner film 3 and the cap film 5 without being exposed to the atmosphere, thereby finely maintaining the moisture-proof condition of the FSG film 4 while insulating fluorine contained in the FSG film 4.

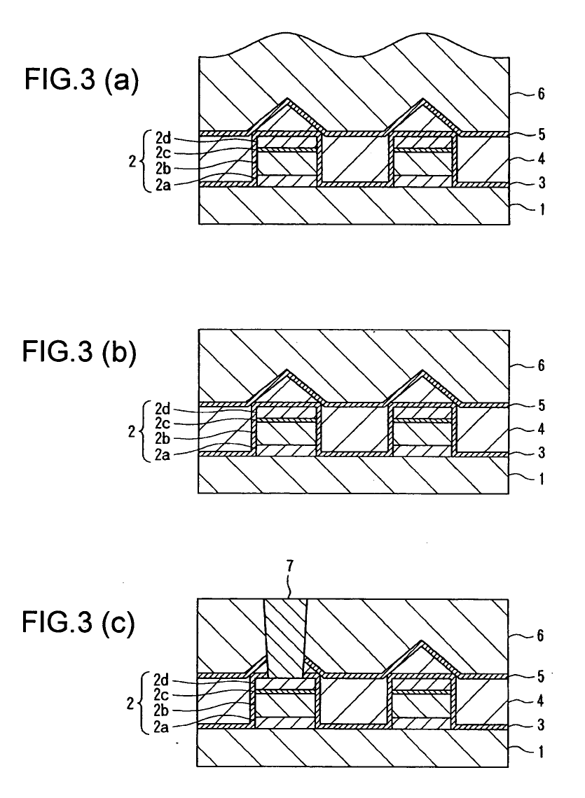

Next, as shown in FIG. 3(a), the silicon oxide film 6 is formed on the cap film 5 by conducting plasma CVD using Tetraethoxysilane (TEOS) gas, for example.

Here, since the FSG film with the cap film 5, it is possible to prevent the FSG film 4 from being exposed to the atmosphere and restrain it from taking up moisture even when replacing the device with another in order to form the silicon oxide film 6 on the cap film 5.

Next, as shown in FIG. 3(b), the surface of the silicon oxide film 6 is polished with Chemical Mechanical Polishing (CMP), for example, so as to be planarized.

Here, forming the silicon oxide film 6 using TEOS plasma CVD can reduce particles of the silicon oxide film 6 and allow the surface of the silicon oxide film 6 to be finely planarized, compared with the case of forming the silicon oxide film 6 using high-density plasma CVD.

Subsequently, as shown in FIG. 3(c), a via-hole is formed in the liner film 3, the FSG film 4, the cap film 5 and the silicon oxide film 6 on the lower wiring layer 2 by photolithography and etching techniques, and tungsten is selectively grown on the lower wiring layer 2. Consequently, the tungsten plug 7 is formed on the lower wiring layer 2.

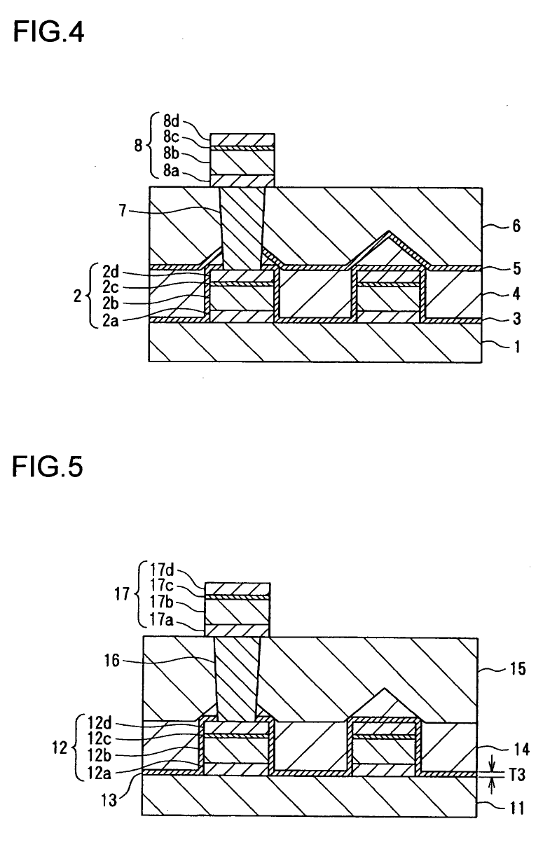

Next, as shown in FIG. 4, for example, TiN, Al-Cu, Ti and TiN are sputtered in turn onto the silicon oxide film 6, and a multi layered film comprising TiN, Al-Cu, Ti and TiN is patterned by photolithography and etching techniques. As a result, the upper wiring layer 8 is formed on the silicon oxide film 7.

FIG. 5 is a sectional view showing a schematic structure of wiring layers in a semiconductor device according to the second embodiment of the invention.

In FIG. 5, a lower wiring layer 12 is formed on an insulating layer 11 and comprises a structure of multi layers including a TiN film 12a, an Al-Cu film 12b, a Ti film 12c and a TiN film 12d, for example.

Here, it is possible to set the thickness of the TiN film 12a to about 300 to 400 Å, for example, that of the Al-Cu film 12b to about 3000-10000 Å, for example, that of the Ti film 12c to about 200 Å, for example, and that of the TiN film 12d to about 600 to 1000 Å, for example.

Furthermore, an FSG film 14 is formed over the lower wiring layer 12 through a liner film 13.

Here, the liner film 13 insulates fluorine contained in the FSG film 14, and for instance, an undoped silicon oxide film may be employed as the liner film 13.

Moreover, a silicon oxide film 15 is formed on the FSG film 14, and in the silicon oxide film 15, a tungsten plug 16 connected to the lower wiring layer 12 is embedded.

Then, on the silicon oxide film 15, an upper wiring layer 17 comprising a structure of four layers including, for example, a TiN film 17a, an Al-Cu film 17b, a Ti film 17c and a TiN film 17d is formed and is connected to the lower wiring layer 12 through the tungsten plug 16.

Here, forming the FSG film 14 through the liner film 13 can prevent fluorine contained in the FSG film 14 from directly contacting with the lower wiring layer 12. It also restrains Ti of the lower wiring layer 12 from getting fluoride even when covering the lower wiring layer 12 with the FSG film 14, so that TiF can thereby be prevented from being formed on the lower wiring layer 12.

Moreover, it is possible to establish a value about 3.2 to 3.8 as a dielectric constant of the FSG film 14, and the dielectric constant can be lowered in comparison with the case of using a silicon dioxide film with a dielectric constant about 4.0 to 4.2.

Therefore, it is possible to lower the dielectric constant of the interlayer insulating film on the lower wiring layer 12 while suppressing increase of a wiring resistance of the lower wiring layer 12. Thereby, a wiring delay is prevented, so that the characteristics of the semiconductor device can be enhanced.

In addition, a thickness T3 of the liner film 13 is preferably about 500 to 700 Å, for example, and thereby it is possible to maintain a gap-fill characteristic and a coverage of the liner film 13 to be formed on the lower wiring layer 12. At the same time, it is possible to suppress an increase of the dielectric constant of the interlayer insulating film formed on the lower wiring layer 12 while keeping fluorine contained in the FSG film 14 from affecting the lower wiring layer 12.

Also, the structure of the lower wiring layer 12 may be the one comprising TiN, Al, Ti and TiN or the one comprising TiN, Al-Cu and TiN, besides the structure of multi layers including the TiN film 12a, the Al-Cu film 12b, the Ti film 12c and the TiN film 12d.

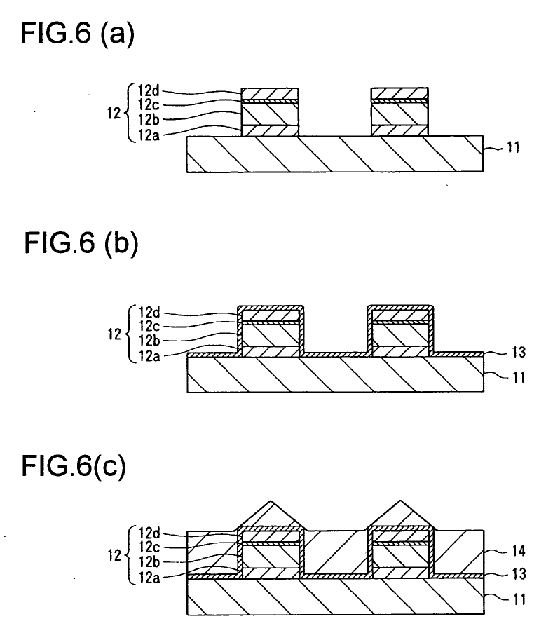

FIG. 6(a) through FIG. 8 are sectional views illustrating a method of forming the wiring layers in the semiconductor device according to the second embodiment of the invention.

In FIG. 6(a), for example, TiN, Al-Cu, Ti and TiN are sputtered in turn onto the interlayer insulating film 11, and a multi layered film comprising TiN, Al-Cu, Ti and TiN is patterned by photolithography and etching techniques so as to form the lower wiring layer 12 on the insulating film 11.

Then, as shown in FIG. 6(b), the liner film 13 such as an undoped silicon oxide film is formed so as to cover the lower wiring layer 12 by a method such as high-density plasma CVD.

Next, as shown in FIG. 6(c), the FSG film 14 is formed on the liner film 13 by a method such as high-density plasma CVD, and is annealed in the nitrogen atmosphere, thereby removing unstable fluorine components in the FSG film 14.

Here, the silicon oxide film is continuously formed by alternating between mixing a fluorine dopant and not mixing a fluorine dopant within the same chamber with the in-situ process, for example, as a method of forming the liner film 13 and the FSG film 14.

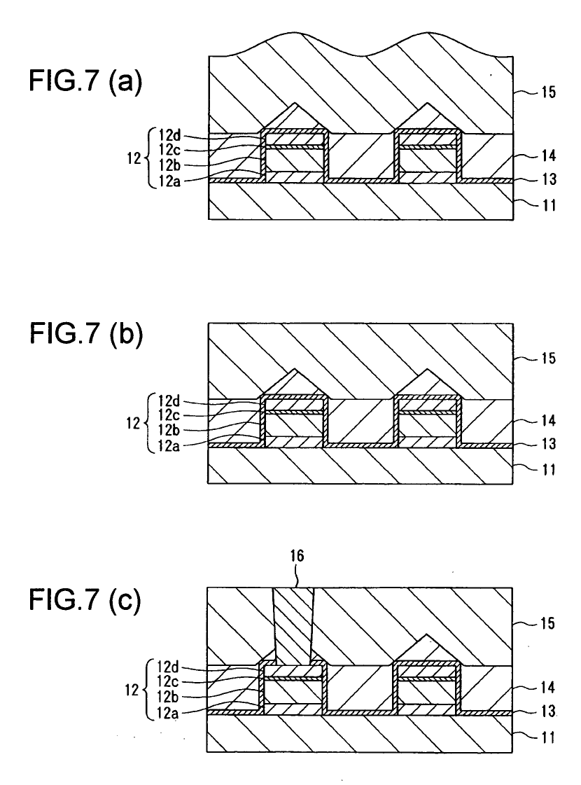

Next, as shown in FIG. 7(a), the silicon oxide film 15 is formed on the FSG film 14 by conducting plasma CVD using Tetraethoxysilane (TEOS) gas, for example.

Then, as shown in FIG. 7(b), the surface of the silicon oxide film 15 is polished, for example, by Chemical Mechanical Polishing (CMP) to be planarized.

Here, forming the silicon oxide film 15 using TEOS plasma CVD can reduce particles of the silicon oxide film 15 and planarize the surface of the silicon oxide film 15 with high precision, compared with the case of forming the silicon oxide film 15 using high-density plasma CVD.

Subsequently, as shown in FIG. 7(c), a via-hole is formed in the liner film 13, the FSG film 14 and the silicon oxide film 15 on the lower wiring layer 12 by photolithography and etching techniques, and tungsten is selectively grown on the lower wiring layer 12. Consequently, the tungsten plug 16 is formed on the lower wiring layer 12.

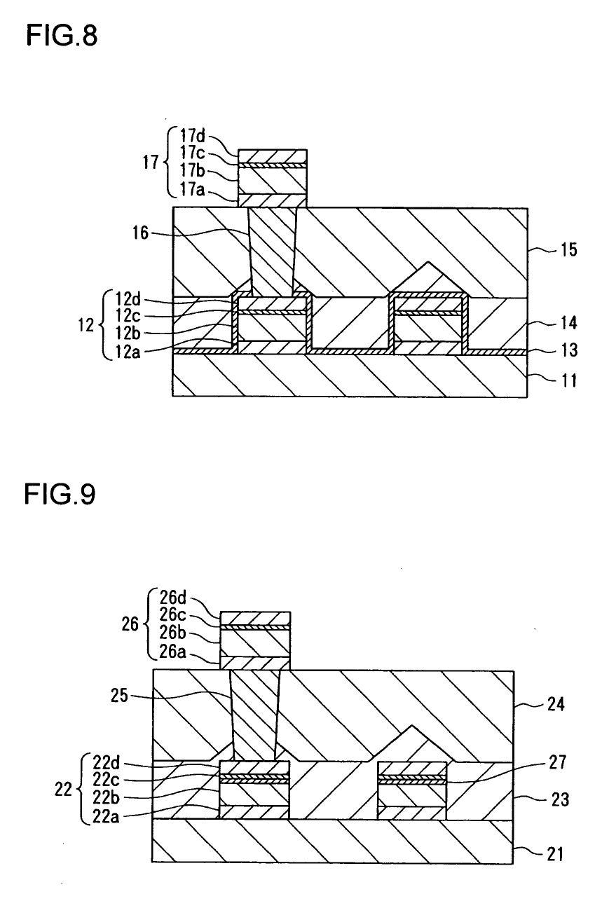

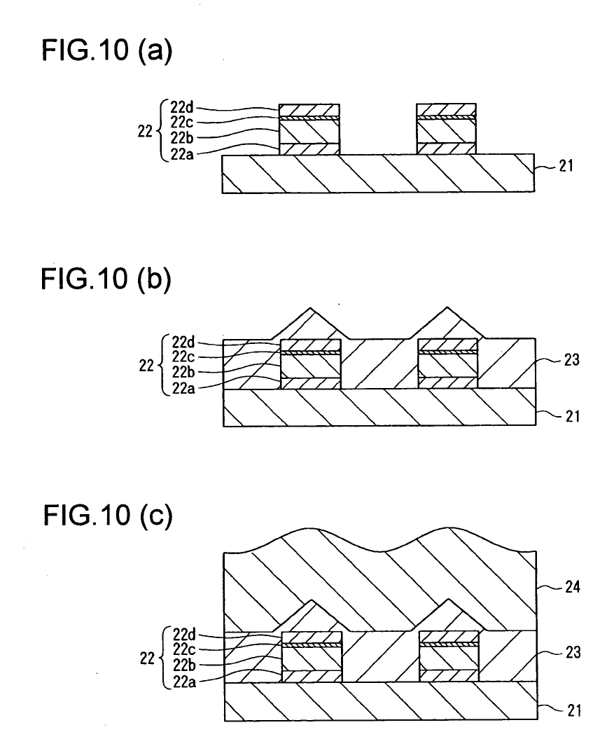

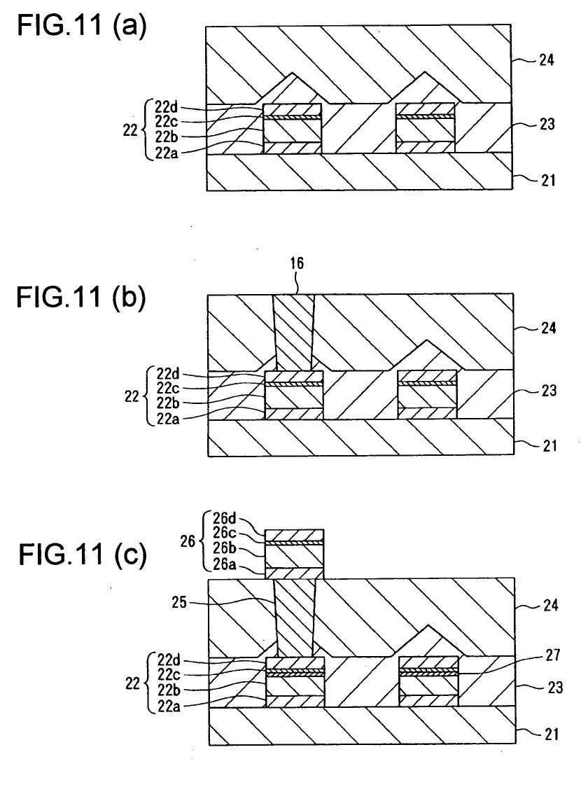

Next, as shown in FIG. 8, for example, TiN, Al-Cu, Ti and TiN are sputtered in turn onto the silicon oxide film 15, and a multi layered film comprising TiN, Al-Cu, Ti and TiN is patterned by photolithography and etching techniques. Thereby, the upper wiring layer 17 is formed on the silicon oxide film 15.

In the above embodiments, the cases of forming the wiring layers in the semiconductor device are explained; however, the wiring forming method of the invention is not limited to application for semiconductor devices and is applicable, for example, to liquid crystal displays, organic EL elements and build up multi-layer wiring boards, besides the semiconductor devices.

According to the invention as described above, it is possible to restrain fluorine contained in a fluorosilicate glass film from detaching therefrom. Moreover, fluorine can also be prevented from affecting and corroding a wiring layer covered with the fluorosilicate glass film. At the same time, increase in a wiring resistance of the wiring layer is suppressed.

What is claimed is:

1. A semiconductor device comprising:
a fluorine-insulating film formed on a wiring layer; and
a fluorosilicate glass film formed above the wiring layer and the fluorine-insulating film.

2. A semiconductor device comprising:
a fluorosilicate glass film for insulating a wiring layer; and
a first and second fluorine-insulating film formed so as to sandwich the fluorosilicate glass film from above and below.

3. The semiconductor device according to claim 1, wherein the fluorine-insulating film comprises an undoped silicon oxide film.

4. The semiconductor device according to claim 1, wherein the wiring layer comprises a structure comprising TiN, Al-Cu, Ti, and TiN.

5. A thin film forming method comprising:
forming an undoped silicon oxide film on a wiring layer; and
forming a fluorosilicate glass film on the undoped silicon oxide film.

6. The thin film forming method according to claim 5, further comprising a step of forming an undoped silicon oxide film on the fluorosilicate glass film.

7. The thin film forming method according to claim 5, wherein the undoped silicon oxide film and the fluorosilicate glass film are continuously formed by alternating between mixing a fluorine dopant and not mixing the fluorine dopant.

8. The semiconductor device according to claim 2, wherein the first and second fluorine-insulating films comprise an undoped silicon oxide film.

9. The semiconductor device according to claim 2, wherein the wiring layer comprises a structure comprising TiN, Al-Cu, Ti, and TiN.

10. The thin film forming method according to claim 6, wherein the undoped silicon oxide film and the fluorosilicate glass film are continuously formed by alternating between mixing a fluorine dopant and not mixing the fluorine dopant.

11. A semiconductor device as set forth in claim 2, wherein said first fluorine insulating film has a thickness of approximately 500 Å to approximately 700 Å, and said second fluorine insulating film has a thickness of approximately 1000 Å.

12. A semiconductor device as set forth in claim 1, wherein said fluorine-insulating film has a thickness of approximately 500 Å to approximately 700 Å.
